(19) United States
(12) Patent Application Publication
(10) Pub. No.: US 2014/0140468 A1
(43) Pub. Date: May 22, 2014

(54) SHIFT REGISTER

(71) Applicant: AU OPTRONICS CORP., Hsin-Chin (TW)

(72) Inventors: Shih-Song CHENG, Hsin-Chu (TW); Chun-Yen LIU, Hsin-Chu (TW)

(73) Assignee: AU OPTRONICS CORP., Hsin-Chu (TW)

(21) Appl. No.: 13/965,298

(22) Filed: Aug. 13, 2013

(30) Foreign Application Priority Data
Nov. 22, 2012 (TW) 101143724

(51) Int. Cl. G11C 19/18

(52) U.S. Cl. CPC G11C 19/184
USPC 377/68

(57) ABSTRACT

A shift register includes a previous signal receiving unit, a next signal receiving unit, a control unit and a voltage stabilizing switch. The shift register controls an outputting signal by continuously stabilized voltage generated from cooperating operation of the units and switch.

### FIELD OF THE INVENTION

The present invention relates to a shift register, and more particularly to a shift register with stabilized outputted control voltages.

### BACKGROUND OF THE INVENTION

A shift register is a kind of electronic component, which is widely used and seen in many electronic products. Generally, plural shift-register stages are connected one by one in series to form a shift register group, and an electronic signal is transmitted from a previous shift register to a next shift register stage. Therefore, the electronic signal can achieve correctly function at different locations in different time due to a delay time of a signal transmission in the shift register group.

Referring to FIG. 1A and FIG. 1B, FIG. 1A is a circuit diagram of a typical shift register, and FIG. 1B is a waveform diagram of signals respectively corresponding to each node in the shift register. Shown as in FIG. 1A and FIG. 1B, the shift register 10 receives an output signal N−1 from (N−1)th shift register, an output signal N+1 from (N+1)th shift register, a clock signal CK, a reversed clock signal XCK, etc. as control signals of the shift register 10. Output voltages respectively from voltage sources VGL and VGH control the amplitude of an output signal N outputted from an output node of the shift register. It is noted that, in FIG. 1A, a stabilized output voltage of the output signal N in a time interval t₁ (shown in FIG. 1B) is controlled by turning on/off P type transistors P1 and P2. Wherein, turning on/off the P type transistor P1 is controlled by a voltage at a node Q, and turning on/off the P type transistor P2 is controlled by the reversed clock signal XCK.

Shown as in FIG. 1B, the voltage of the reversed clock signal XCK and the voltage at the node Q both are voltages with periodic repetition. Due to the design, the P type transistors P1 and P2 can supply the voltage of the source VGH to the output node in turn. However, because the operation of turning on/off the transistors needs transition time, when switching on/off of the P type transistors P1 and P2, the voltage of the output signal N is liable to be unstable.

### SUMMARY OF INVENTION

An exemplary embodiment of the present invention provides a shift register. The shift register includes a previous signal receiving unit, a next signal receiving unit, a control unit, and a voltage stabilizing switch. The previous signal receiving unit includes a previous signal input terminal, a previous first preset-voltage input terminal, a previous second preset-voltage input terminal, a previous first control-signal output terminal, and a previous second control-signal output terminal. The previous signal input terminal receives a previous signal, the previous first preset-voltage input terminal is electrically coupled to a first preset-voltage source, the previous second preset-voltage input terminal is electrically coupled to a second preset-voltage source, and the previous signal receiving unit controls degrees of an electrical conduction between the previous first preset-voltage input terminal and the previous first control-signal output terminal according to a voltage of the previous signal, and controls degrees of an electrical conduction between the previous second preset-voltage input terminal and the previous second control-signal output terminal according to the voltage of the previous signal. The next signal receiving unit includes a next signal input terminal, a next second preset-voltage input terminal, and a next control-signal output terminal. The next signal input terminal receives a next signal, the next second preset-voltage input terminal is electrically coupled to the second preset-voltage source, the next control-signal output terminal is electrically coupled to the previous first control-signal output terminal, and the next signal receiving unit controls degrees of an electrical conduction between the next second preset-voltage input terminal and the next control-signal output terminal according to a voltage of the next signal. The control unit includes a first preset-voltage input terminal, a clock-signal input terminal, a reversed clock-signal input terminal, a first control-signal input terminal, a second control-signal input terminal, and an output terminal. The first preset-voltage input terminal is electrically coupled to the preset voltage source, the clock-signal input terminal receives a clock signal, the reversed clock-signal input terminal receives a reversed clock signal having a phase reverse to that of the clock signal, the first control-signal input terminal is electrically coupled to the previous first control-signal output terminal, the second control-signal input terminal is electrically coupled to the previous second control-signal output terminal, and the control unit controls degrees of an electrical conduction between the clock-signal input terminal and the output terminal according to voltages of the reversed clock-signal input terminal, the first control-signal input terminal and the second control-signal input terminal. The voltage stabilizing switch includes a control terminal, a first source/drain terminal and a second source/drain terminal. The control terminal is electrically coupled to the output terminal of the control unit, the first source/drain terminal is electrically coupled to the previous first control-signal output terminal, and the second source/drain terminal is electrically coupled to the previous first preset-voltage input terminal of the previous signal receiving unit.

Another exemplary embodiment of the present invention provides a shift register. The shift register includes a driving-signal generating module and a driving module. The driving-signal generating module provides a first driving signal and a second driving signal, and a phase of the first driving signal is reverse to a phase of the second driving signal. The driving module includes a first input terminal, a second input terminal, a driving module first preset-voltage input terminal, a driving module second preset-voltage input terminal, an enable-signal input terminal, and a driving-signal output terminal. The driving module is electrically coupled to the driving-signal generating module to receive the first driving signal via the first input terminal and receive the second driving signal via the second input terminal, and the driving module controls degrees of an electrical conduction between the driving module first preset-voltage input terminal and the driving-signal output terminal according to the first driving signal, and controls degrees of an electrical conduction between the enable-signal input terminal and the driving-signal output terminal according to the second driving signal. An enabled duration of the enable-signal input terminal determines an enabled duration of the driving-signal output terminal.

### BRIEF DESCRIPTION OF THE DRAWINGS

FIG. 1A is a circuit diagram of a conventional shift register.

FIG. 1B is a waveform diagram of signals respectively corresponding to each node in the shift register in FIG. 1A.

FIG. 2 is a block diagram of a shift register according to an embodiment of the present invention.

FIG. 3A is a circuit diagram of a shift register according to an embodiment of the present invention.

FIG. 3B is an operating timing diagram of the shift register shown in FIG. 3A.

FIG. 4 is a circuit diagram of a shift register according to another embodiment of the present invention.

FIG. 5 is a circuit diagram of a shift register according to another more embodiment of the present invention.

FIG. 6 is a block diagram of a shift register according to another embodiment of the present invention.

FIG. 7A is a circuit diagram of a driving-signal generating module according to an embodiment of the present invention.

FIG. 7B is a circuit diagram of a driving module according to an embodiment of the present invention.

FIG. 7C is a waveform diagram of signals respectively corresponding to each node when the circuit in FIG. 7B operates.

FIG. 8A is a circuit diagram of a shift register according to another more again embodiment of the present invention.

FIG. 8B is a waveform diagram of signals respectively corresponding to each node when the shift register in FIG. 8A operates.

### DETAILED DESCRIPTION OF EMBODIMENTS

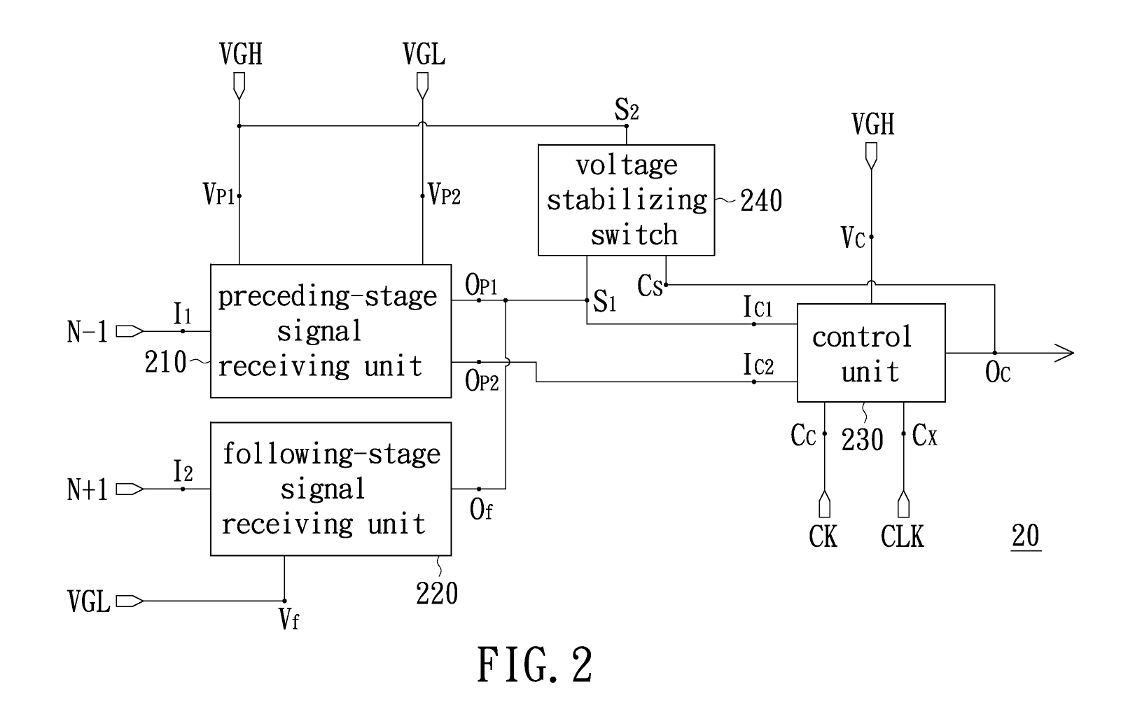

Referring to FIG. 2, FIG. 2 is a block diagram of a shift register according to an embodiment of the present invention. In this embodiment, supposing that the shift register 20 is the Nth stage of a shift register group, the shift register 20 includes an (N−1)th (previous) signal receiving unit 210, an (N+1)th (next) signal receiving unit 220, a control unit 230, and a voltage stabilizing switch 240.

The (N−1)th signal receiving unit 210 has an (N−1)th signal input terminal I₁, an (N−1)th first preset-voltage input terminal V_{P1}, an (N−1)th second preset-voltage input terminal V_{P2}, an (N−1)th first control-signal output terminal O_{P1}, and an (N−1)th second control-signal output terminal O_{P2}. The (N−1)th signal input terminal I₁ receives an (N−1)th signal N−1 outputted from an (N−1)th shift register. The (N−1)th first preset-voltage input terminal V_{P1} is electrically coupled to a preset voltage source VGH. The (N−1)th second preset-voltage input terminal V_{P2} is electrically coupled to a preset voltage source VGL. The detailed circuit design of the (N−1)th signal receiving unit 210 will be illustrated as follows by examples and referring to other drawings. However, in summary, the circuit design is needed to make the (N−1)th signal receiving unit 210 capable of controlling degrees of an electrical conduction between the (N−1)th first preset-voltage input terminal V_{P1} and the (N−1)th first control-signal output terminal O_{P1} according to a voltage of the (N−1)th signal N−1, and capable of controlling degrees of an electrical conduction between the (N−1)th second preset-voltage input terminal V_{P2} and the (N−1)th second control-signal output terminal O_{P2} according to the voltage of the (N−1)th signal N−1.

The (N+1)th signal receiving unit 220 has an (N+1)th signal input terminal I₂, an (N+1)th second preset-voltage input terminal V_{f}, and an (N+1)th control-signal output terminal O_{f}. The (N+1)th signal input terminal I₂ receives an (N+1)th signal N+1 outputted from an (N+1)th shift register. The (N+1)th second preset-voltage input terminal V_{f} is electrically coupled to the preset voltage source VGL. The (N+1)th control-signal output terminal O_{f} is electrically coupled to the (N−1)th first control-signal output terminal O_{P1} of the (N−1)th signal receiving unit 210. The detailed circuit design of the (N+1)th signal receiving unit 220 will be illustrated as follows by examples and referring to other drawings. However, in summary, the circuit design is needed to make the (N+1)th signal receiving unit 220 capable of controlling degrees of an electrical conduction between the (N+1)th second preset-voltage input terminal V_{f} and the (N+1)th control-signal output terminal O_{f} according to a voltage of the (N+1)th signal N+1.

The control unit 230 has a first preset-voltage input terminal V_{C}, a clock-signal input terminal C_{C}, a reversed clock-signal input terminal C_{X}, a first control-signal input terminal I_{C1}, a second control-signal input terminal I_{C2}, and an output terminal O_{C}. The first preset-voltage input terminal V_{C} is electrically coupled to the preset voltage source VGH. The clock-signal input terminal C_{C} receives a clock signal CK, and the reversed clock-signal input terminal C_{X} receives a reversed clock signal XCK which has a phase reverse to that of the clock signal CK. The first control-signal input terminal I_{C1} is electrically coupled to the (N−1)th first control-signal output terminal O_{P1} of the (N−1)th signal receiving unit 210, and the second control-signal input terminal I_{C2} is electrically coupled to the (N−1)th second control-signal output terminal O_{P2} of the (N−1)th signal receiving unit 210. The detailed circuit design of the control unit 230 will be illustrated as follows by examples and referring to other drawings. However, in summary, the circuit design is needed to make the control unit 230 capable of controlling degrees of an electrical conduction between the clock-signal input terminal C_{C} and the output terminal O_{C} according to a voltage of the reversed clock signal XCK, a voltage at the first control-signal input terminal I_{C1} and a voltage at the second control-signal input terminal I_{C2}.

The voltage stabilizing switch 240 has a control terminal C_{S}, and two source/drain terminals S₁ and S₂. The control terminal C_{S} is electrically coupled to the output terminal O_{C} of the control unit 230. The source/drain terminal S₁ is electrically coupled to the (N−1)th first control-signal output terminal O_{P1} of the (N−1)th signal receiving unit 210, and the source/drain terminal S₂ is electrically coupled to the (N−1)th first preset-voltage input terminal V_{P1} of the (N−1)th signal receiving unit 210.

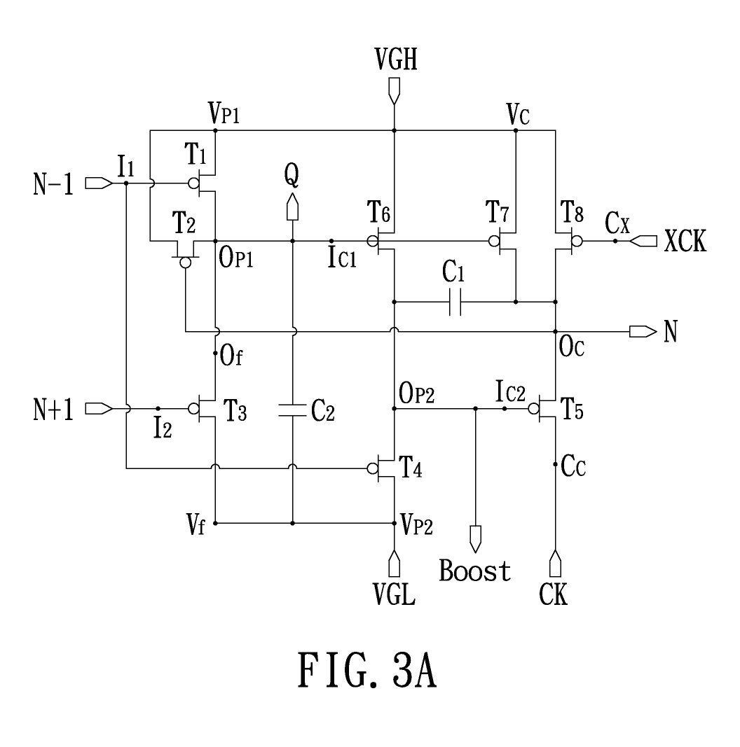

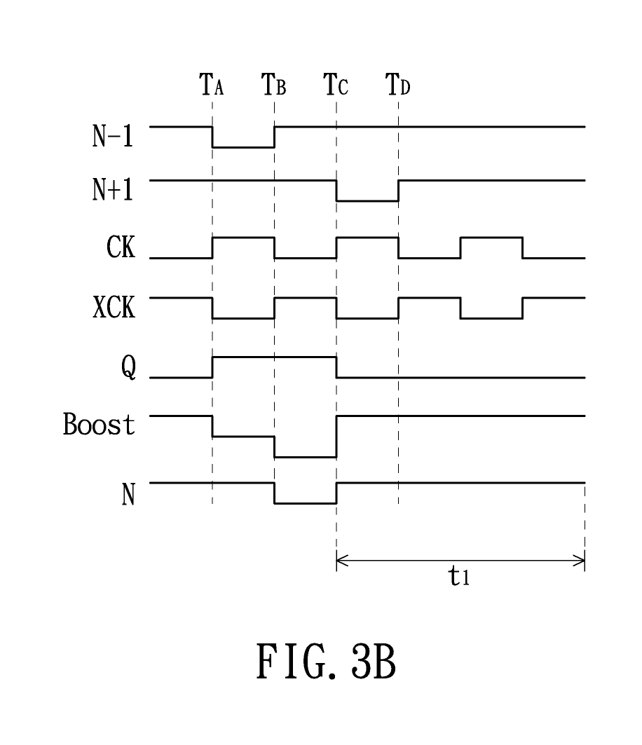

Referring to FIG. 3A, FIG. 3A is a circuit diagram of a shift register according to an embodiment of the present invention. In this embodiment, the (N−1)th signal receiving unit 210 shown in FIG. 2 includes P type transistors T₁ and T₄. The (N+1)th signal receiving unit 220 includes a P type transistor T₃ and a capacitor C₂. The control unit 230 includes P type transistors T₅, T₆, T₇ and T₈, and capacitor C₁. The voltage stabilizing switch 240 includes P type transistor T₂.

Shown in FIG. 3A, each of the P type transistors T₁-T₈ has a control terminal, and two source/drain terminals, and each of the capacitors C₁ and C₂ has two source/drain terminals. In this embodiment, the control terminal of the P type transistor T₁ is electrically coupled to the (N−1)th signal input terminal I₁, or in other words, the control terminal of the P type transistor T₁ is used as the (N−1)th signal input terminal I₁. Furthermore, one source/drain terminal of the P type transistor T₁ is electrically coupled to the (N−1)th first control-signal output terminal O_{P1} and a node Q, and the other source/drain terminal of the P type transistor T₁ is electrically coupled to the (N−1)th first preset-voltage input terminal V_{P1} to receive a voltage provided by the preset voltage source VGH. The control terminal of the P type transistor T₂ is electrically coupled to the output terminal O_{C} of the control unit 230 shown in FIG. 2. One source/drain terminal of the P type transistor T₂ is electrically coupled to the (N−1)th first control-signal output terminal O_{P1} and the node Q, and the other source/drain terminal of the P type transistor T₂ is electrically coupled to the (N−1)th first preset-voltage input terminal V_{P1} to be electrically coupled to the preset voltage source VGH.

The control terminal of the P type transistor T₃ is electrically coupled to the (N+1)th signal input terminal I₂, or in other words, the control terminal of the P type transistor T₃ is used as the (N+1)th signal input terminal I₂. Furthermore, one source/drain terminal of the P type transistor T₃ is electrically coupled to the (N+1)th second preset-voltage input terminal V_{f}, and the other source/drain terminal of the P type transistor T₃ is electrically coupled to the (N+1)th control-signal output terminal O_{f}, and is also electrically coupled to the node Q like as the (N−1)th first control-signal output terminal O_{P1}. The control terminal of the P type transistor T₄ is also electrically coupled to the (N−1)th signal input terminal I₁ like as the P type transistor T₁, one source/drain terminal of the P type transistor T₄ is electrically coupled to the (N−1)th second preset-voltage input terminal V_{P2}, and the other source/drain terminal of the P type transistor T₄ is electrically coupled to the (N−1)th second control-signal output terminal O_{P2}.

The control terminal of the P type transistor T₅ is electrically coupled to the second control-signal input terminal I_{C2}, and thereby is electrically coupled to the (N−1)th second control-signal output terminal O_{P2}. One source/drain terminal of the P type transistor T₅ is electrically coupled to the clock-signal input terminal C_{C} to receive the clock signal CK, and the other source/drain terminal of the P type transistor T₅ is electrically coupled to the output terminal O_{C}. The control terminal of the P type transistor T₆ is electrically coupled to the first control-signal input terminal I_{C1}, and thereby is electrically coupled to the (N−1)th first control-signal output terminal O_{P1}. One source/drain terminal of the P type transistor T₆ is electrically coupled to the second control-signal input terminal I_{C2}, and thereby is electrically coupled to the (N−1)th second control-signal output terminal O_{P2}. The other source/drain terminal of the P type transistor T₆ is electrically coupled to the (N−1)th first preset-voltage input terminal V_{P1} to receive a voltage provided by the preset voltage source VGH.

The control terminal of the P type transistor T₇ is electrically coupled to the first control-signal input terminal I_{C1}, and thereby is also electrically coupled to the (N−1)th first control-signal output terminal O_{P1} like as the control terminal of the P type transistor T₆. One source/drain terminal of the P type transistor T₇ is electrically coupled to the output terminal O_{C}, and the other source/drain terminal of the P type transistor T₇ is electrically coupled to the first preset-voltage input terminal V. The two source/drain terminals of the P type transistor T₈ are electrically coupled to the two source/drain terminals of the P type transistor T₇, and the control terminal of the P type transistor T₈ is electrically coupled to the reversed clock-signal input terminal C_{X} to receive the reversed clock signal XCK. Finally, one terminal of the capacitor C₁ is electrically coupled to the output terminal O_{C}, and the other terminal of the capacitor C₁ is electrically coupled to the second control-signal input terminal I_{C2}. One terminal of the capacitor C₂ is electrically coupled to the (N+1)th second preset-voltage input terminal V_{f}, and the other terminal of the capacitor C₁ is electrically coupled to the (N+1)th control-signal output terminal O_{f}, and thereby is electrically coupled to the (N−1)th first control-signal output terminal O_{P1}.

Referring to FIG. 3A and FIG. 3B, FIG. 3B is an operating timing diagram of the shift register shown in FIG. 3A, assuming that logic low level is enable level, the logic high level is non-enable level, the preset voltage source VGH provides a voltage with logic high level, and the preset voltage source VGL provides a voltage with logic low level. So shown as in FIG. 3A and FIG. 3B, before the time point T_{A}, the (N−1)th signal N−1 outputted from the (N−1)th shift register and the (N+1)th signal N+1 outputted from the (N+1)th shift register both are at logic high level (that is, in non-enable state), and the clock signal CK and the reversed clock signal XCK sustain periodic changes with the phase reverse to each other. At this time, the P type transistors T₁, T₃ and T₄ are turned off due to being controlled by the (N−1)th signal N−1 and the (N+1)th signal N+1, and other P type transistors, the node Q, node Boost and an output signal N outputted by the output terminal O_{C}, each keep at a specific level. Briefly, before the time point T_{A}, the level at each node in the shift register 20 keeps in one of three kinds of specific level because of being in an initialized state, an operation result of the shift register 20 in previous time, or level changes due to the turning on/off of the P type transistors T₈ by the reversed clock signal XCK.

Next, between the time point T_{A} and the time point T_{B}, the (N−1)th signal N−1 is turned from the logic high level to the logic low level, therefore the P type transistors T₁ and T₄ are turned on. The voltage of the node Q is pulled up to be equal or close to the voltage provided by the preset voltage source VGH (that is, the logic high level). In contrast, the voltage of the node Boost is pulled down to be equal or close to the voltage provided by the preset voltage source VGL (that is, the logic low level). At this time, the node Q at the logic high level makes the P type transistors T₆ and T₇ being turned on. In opposite, the node Boost at the logic low level makes the P type transistor T₅ being turned on, and the reversed clock signal XCK at the logic low level makes the P type transistor T₈ being turned on. Therefore, the output signal N is pulled up to the logic high level to make the P type transistor T₂ being turned off.

Between the time point T_{B} and the time point T_{C}, the (N−1)th signal N−1 is turned from the logic low level to the logic high level, therefore the P type transistors T₁ and T₄ are turned off. In addition, the (N+1)th signal N+1 keeps at the logic high level, and the P type transistor T₃ keeps in a turned-off state. During this time, the reversed clock signal XCK is turned from the logic low level to the logic high level, the P type transistor T₈ is accordingly turned off, and the preset voltage source VGH thereby cannot influence the voltage of the output signal N via the P type transistor T₈. However, due to the clock signal CK being turned from the logic high level to the logic low level, except the voltage of the node Boost is further pulled down, the voltage of the output signal N is pulled down to be almost the same logic low level as the clock signal CK due to the P type transistor T₅ keeping in a turned-on state. The output signal N being pulling down turns on the P type transistor T₂, and makes the voltage of the node Q thereby keeping being equal or close to the voltage provided by the preset voltage source VGH. Furthermore, the P type transistors T₆ and T₇ thereby keep in the turned-on state to ensure a stabilized operation of the whole circuit.

Between the time point T_{C} and the time point T_{D}, the (N+1)th signal N+1 is turned from the logic high level to the logic low level, the P type transistor T₃ is accordingly turned on, and makes the voltage of the node Q being pulled down to be equal or close to the voltage provided by the preset voltage source VGL. Due to the node Q being pulled down to the logic low level, the P type transistors T₆ and T₇ are turned on, and further make the voltages of the node Boost and the output signal N being accordingly pulled up to be equal or close to the logic high level. In this state, the P type transistor T₅ is turned off due to the node Boost being at the logic high level, and the clock signal CK thereby cannot influence the voltage of the output signal N. In contrast, the reversed clock signal XCK at the logic low level accordingly turns on the P type transistor T₈, and the output signal N is also pulled up to be equal or close to the logic high level by being electrically coupled to the preset voltage source VGH via the P type transistor T₈. Furthermore, due to the output signal N being turned to the logic high level, the P type transistor T₂ is accordingly turned off. Due to the (N−1)th signal N−1 being still at the logic high level, the P type transistor T₁ is in the turned-off state. Therefore, the voltage of the node Q keeps at the logic low level and is not pulled up the logic high level provided by the preset voltage source VGH.

After the time point T_{D}, the (N−1)th signal N−1 and the (N+1)th signal N+1 both keeps at the logic high level, and the P type transistors T₁, T₃ and T₄ are accordingly turned off. Due to the node Q being at the logic low level, the P type transistors T₆ and T₇ are turned off, and the node Boost and the output signal N are thereby at the logic high level. The output signal N at the logic high level controls the P type transistor T₂ to be turned off. When the P type transistors T₁ and T₂ are turned off, the node Q cannot being electrically coupled to the preset voltage source VGH. Therefore, the voltage of the node Q keeps at the logic low level, and further ensures a stabilized operation of the whole circuit.

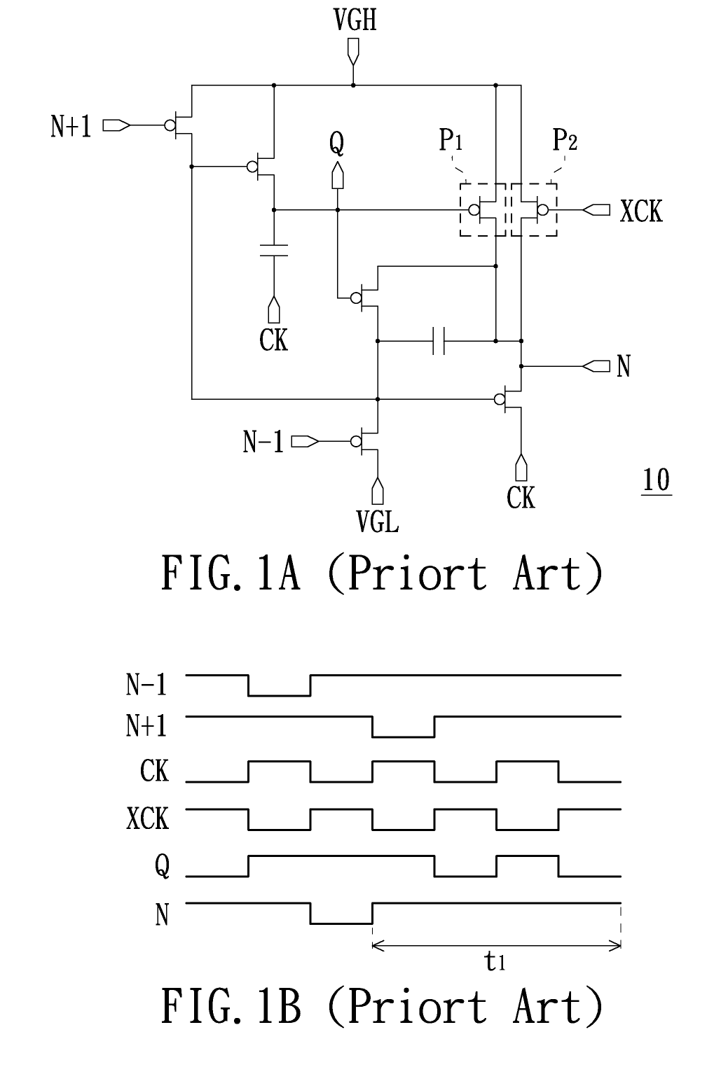

In summary, the voltage of the node Q keeps at a stabilized level in the time interval t₁ after the time point T_{C}, therefore, the P type transistor T₇ can keep in a stabilized turned-on state, and make the output signal N having a stabilized pulling up voltage source (that is, the preset voltage source VGH). In comparison with the unstable output signal N due to the periodic changes of the voltage at the node Q in the time interval t₁ shown in FIG. 1B, the circuit configuration provided by the above embodiment undoubtedly can make the voltage of the output signal N more stabilized.

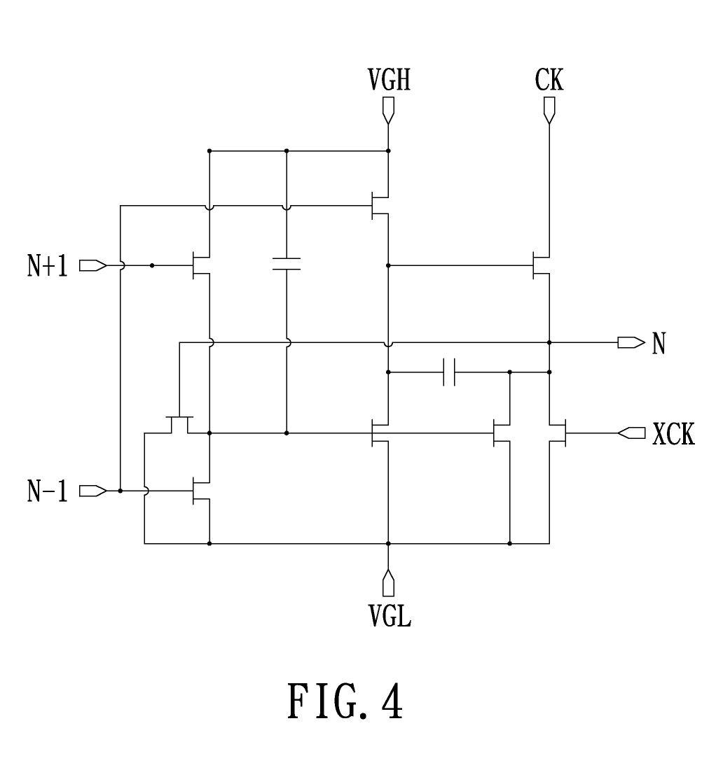

It should be noted that, although the above embodiment is illustrated by taking the P type transistors as an example, the relative circuit composed all by N type transistors actually can be also employed. Referring to FIG. 4, FIG. 4 is a circuit diagram of a shift register according to another embodiment of the present invention. In this embodiment, the connection between the transistors is the same as that shown in FIG. 3A, so it is not excessively described in detail here. However, the logic low level is a preferred choice to enable the N type transistors, therefore, the portion electrically coupled to the preset voltage source VGH shown in FIG. 3A is changed to be electrically coupled to the preset voltage source VGL shown in FIG. 4, and the portion electrically coupled to the preset voltage source VGL shown in FIG. 3A is changed to be electrically coupled to the preset voltage source VGH shown in FIG. 4. The timing diagram generated in operating of the circuit shown in FIG. 4 is similar to that shown in FIG. 3B, it merely needs to exchange the logic high level and the logic low level of the timing diagram shown in FIG. 3B to obtain the timing diagram proper to the circuit shown in FIG. 4. Furthermore, the operation principle is similar to the embodiment illustrated by FIGS. 3A and 3B, and it is not excessively described in detail here.

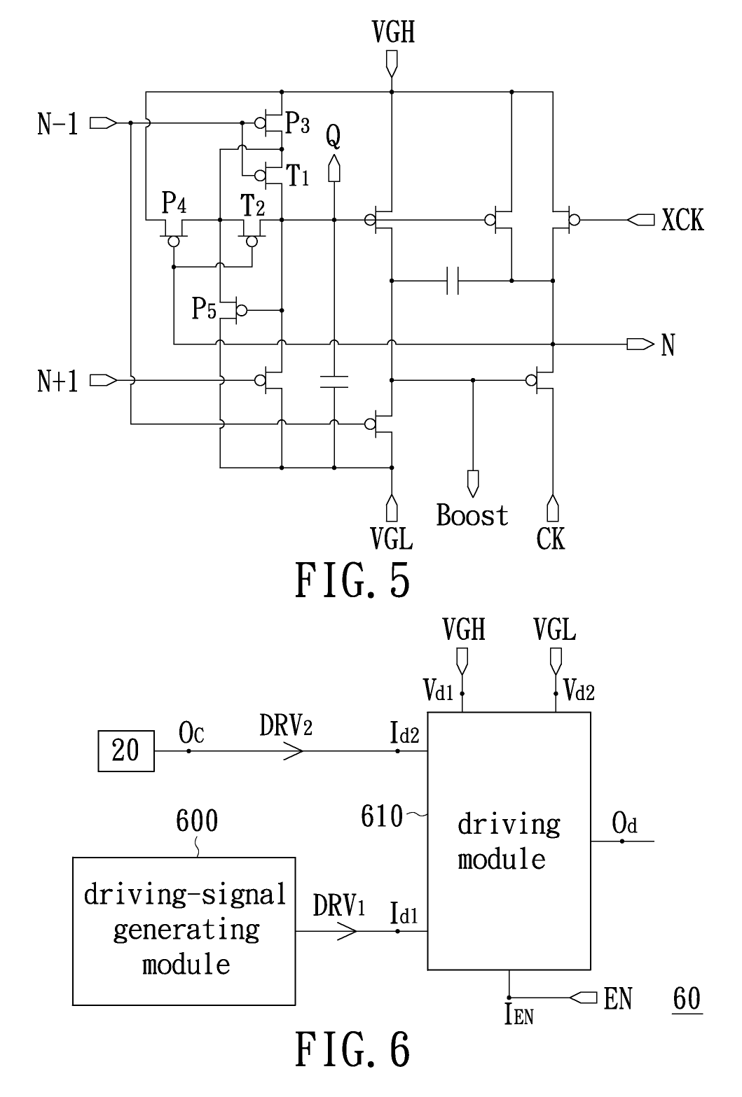

Expect that the target of stabilizing the voltage of the output signal N is achieved by continuously stabilizing the voltage of the node Q, the phenomenon that the voltage is unstable due to the leakage current of the transistors can be further considered. Referring to FIG. 5, FIG. 5 is a circuit diagram of a shift register according to another more embodiment of the present invention. The shift register of this embodiment includes three more P type transistors P₃, P₄ and P₅ than the shift register shown in FIG. 3A to reduce the change generated in the voltage at the node Q caused by the leakage current of the transistors. In this embodiment, the P type transistor P₃ is electrically coupled between the P type transistor T₁ (corresponding to the P type transistor T₁ shown in FIG. 3A) and the preset voltage source VGH, the P type transistor P₄ is electrically coupled between the P type transistor T₂ (corresponding to the P type transistor T₂ shown in FIG. 3A) and the preset voltage source VGH, and the P type transistor P₅ is electrically coupled between the P type transistor T₂ and the preset voltage source VGL.

Referring also to FIG. 2, shown as in FIGS. 2 and 5, a control terminal of the P type transistor P₃ also receives the (N−1)th signal N−1 like as the control terminal of the P type transistor T₁, or the control terminals of the P type transistors P₃ and T₁ both are electrically coupled to the (N−1)th signal input terminal I₁ shown in FIG. 2. One source/drain terminal of the P type transistor P₃ is electrically coupled to the node Q, or is also electrically coupled to the (N−1)th first preset-voltage input terminal V_{P1} of the (N−1)th signal receiving unit 210 shown in FIG. 2, and is thereby electrically coupled to the source/drain terminal of the P type transistor T₁. The other source/drain terminal of the P type transistor P₃ is electrically coupled to the preset voltage source VGH. Therefore, the P type transistors P₃ and T₁ are simultaneously turned on/off, and a time of the P type transistor P₃ influencing the voltage at the node Q almost equals to a time of the P type transistor T₁ influencing the voltage at the node Q.

Referring also to FIG. 3B, because the P type transistor T₁ is turned off after the time point T_{B} shown in FIG. 3B due to the (N−1)th signal N−1 being turned to the logic high level, the P type transistor P₃ is also turned off after the time point T_{B}, and the voltage between the P type transistors T₁ and P₃ keeps at the logic high level. After the voltage of the node Q is pulled down to the logic low level at the time point T_{C}, although the leakage current may be generated at the beginning due to the voltage difference between the two source/drain terminals of each of the P type transistors T₁ and T₂, the almost same voltage between the two source/drain terminals of the P type transistors P₃ can occlude the flow of such leakage current.

Referring to FIGS. 2 and 5, a control terminal of the P type transistor P₄ also receives the output signal N like as the control terminal of the P type transistor T₂, or the control terminals of the P type transistors P₄ and T₂ both are electrically coupled to the output terminal O_{C} of the control unit 230 shown in FIG. 2. One source/drain terminal of the P type transistor P₄ is electrically coupled to the (N−1)th first preset-voltage input terminal V_{P1} shown in FIG. 2, and is thereby electrically coupled to the source/drain terminal of the P type transistor T₂. The other source/drain terminal of the P type transistor P₄ is electrically coupled to the preset voltage source VGH. Therefore, the P type transistors P₄ and T₂ are simultaneously turned on/off, and a time of the P type transistor P₄ influencing the voltage at the node Q almost equals to a time of the P type transistor T₂ influencing the voltage at the node Q.

Referring also to FIG. 3B, because the P type transistor T₂ is turned off after the time point T_{C} shown in FIG. 3B due to the output signal N being turned to the logic high level, the P type transistor P₄ is also turned off after the time point T_{C}, and the voltage between the P type transistors T₂ and P₄ keeps at the logic high level. After the voltage of the node Q is pulled down to the logic low level at the time point T_{C}, although the leakage current may be generated at the beginning due to the voltage difference between the two source/drain terminals of each of the P type transistors T₁ and T₂, the almost same voltage between the two source/drain terminals of the P type transistors P₄ can occlude the flow of such leakage current.

Referring again to FIGS. 2 and 5, a control terminal of the P type transistor P₅ is electrically coupled to the (N−1)th first control-signal output terminal O_{P1} of the (N−1)th signal receiving unit 210 shown in FIG. 2, and is thereby electrically coupled to the node Q. One source/drain terminal of the P type transistor P₅ is electrically coupled to the preset voltage source VGH, and the other source/drain terminal of the P type transistor P₅ is electrically coupled to the (N−1)th first preset-voltage input terminal V_{P1} of the (N−1)th signal receiving unit 210.

Referring also to FIG. 3B, because the voltage of the node Q is pulled down to the logic low level after the time point T_{C}, the P type transistor P₅ is turned on after the time point T_{C} due to the control terminal of the P type transistor P₅ is electrically coupled to the node Q. Due to the P type transistor P₅ being turned on, the source/drain terminal of the P type transistor T₁ connected to the P type transistor P₃, and the source/drain terminal of the P type transistor T₂ connected to the P type transistor P₃ are pulled down to be equal or close to the logic low level provided by the preset voltage source VGL. Therefore, the leakage current caused by the voltage difference between the two source/drain terminals of the P type transistor T₁ decreases or even disappears. Similarly, the leakage current caused by the voltage difference between the two source/drain terminals of the P type transistor T₂ decreases or even disappears.

In summary, after the time point T_{C} shown in FIG. 3B, the P type transistors P₃ and P₄ are added into the circuit to occlude the flow of the leakage current at early period, and the P type transistor P₅ is further added to decrease or eliminate the leakage current generated by the P type transistors T₁ and T₂.

Similarly, several N type transistors can be added into an circuit configuration composed all by N type transistors to achieve the same target. Such circuit configuration and the operation principle are similar to the above embodiment, and it is not excessively described in detail here.

Referring to FIG. 6, FIG. 6 is a block diagram of a shift register according to another embodiment of the present invention. In this embodiment, the shift register 60 includes the circuit configuration of the shift register 20 shown in FIG. 2, and further includes a driving-signal generating module 600 and a driving module 610. The driving-signal generating module 600 provides a driving signal DRV₁, and the phase of the driving signal DRV₁ is reverse to the phase of a driving signal DRV₂ (that is, the above output signal N) outputted from the output terminal O_{C} of the control unit 230 shown in FIG. 2.

In this embodiment, the driving module 610 has two input terminals I_{d1} and I_{d2}, a driving module first preset-voltage input terminal V_{d1}, a driving module second preset-voltage input terminal V_{d2}, an enable-signal input terminal I_{EN}, and a driving-signal output terminal O_{d}. The input terminal L is electrically coupled to the driving-signal generating module 600 to receive the driving signal DRV₁, and the input terminal I_{d2} is electrically coupled to the output terminal O_{C} of the control unit 230 to receive the driving signal DRV₂. The detailed circuit design of the driving module 610 will be illustrated as follows by examples and referring to other drawings. However, in summary, the circuit design is needed to make the driving module 610 capable of controlling degrees of an electrical conduction between the driving module first preset-voltage input terminal V_{d1} and the driving-signal output terminal O_{d} according to the first driving signal DRV₁, and capable of controlling degrees of an electrical conduction between the enable-signal input terminal I_{EN} and the driving-signal output terminal O_{d} according to the second driving signal DRV₂.

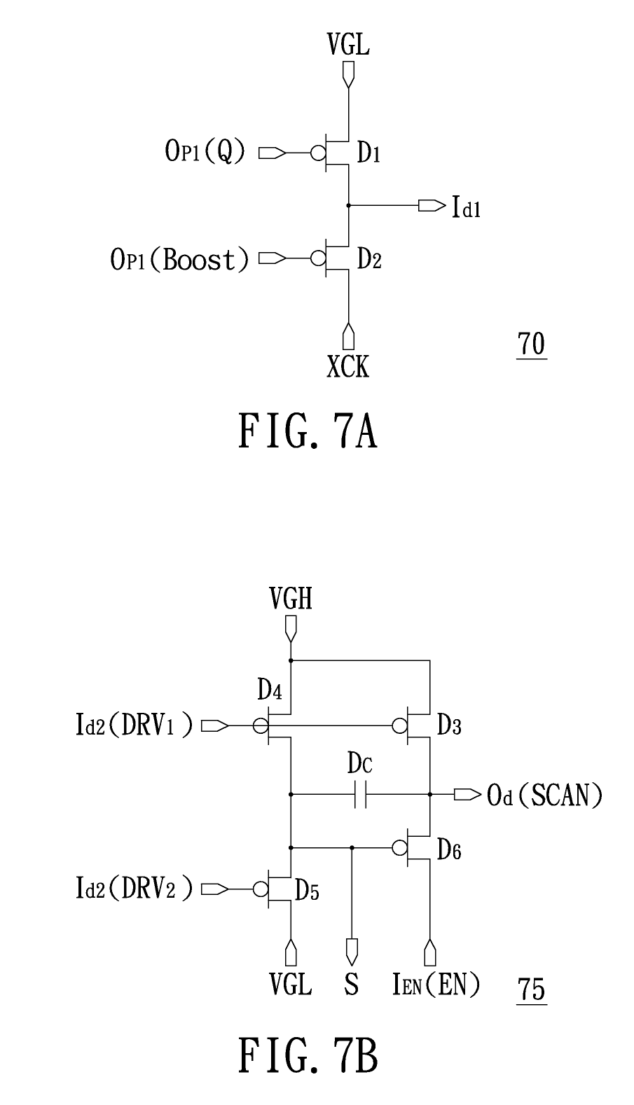

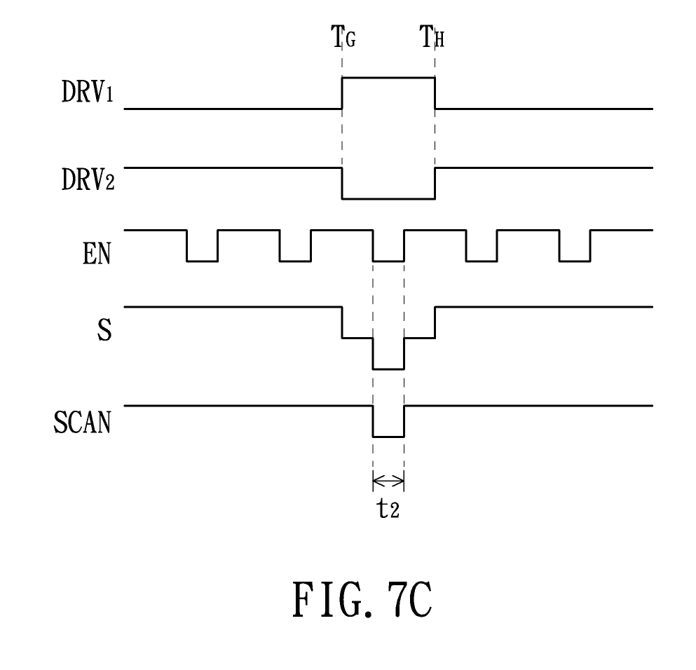

Referring to FIG. 7A, FIG. 7A is a circuit diagram of a driving-signal generating module according to an embodiment of the present invention. In this embodiment, the driving-signal generating module 70 includes two P type transistors D₁ and D₂, and each of the P type transistors includes a control terminal and two source/drain terminals. Referring also to FIG. 3A, the control terminal of the P type transistor D₁ is electrically coupled to the (N−1)th first control-signal output terminal O_{P1}, and is correspondingly electrically coupled to the node Q. One source/drain terminal of the P type transistor D₁ is electrically coupled to the input terminal I_{dl} of the driving module 610, and the other source/drain terminal of the P type transistor D₁ is electrically coupled to the preset voltage source VGL. The control terminal of the P type transistor D₂ is electrically coupled to the (N−1)th second control-signal output terminal O_{P2}, and is correspondingly electrically coupled to the node Boost. One source/drain terminal of the P type transistor D₂ receives the reversed clock signal XCK, and the other source/drain terminal of the P type transistor D₂ is electrically coupled to the input terminal I_{d1} of the driving module 610

Referring to FIG. 7B, FIG. 7B is a circuit diagram of a driving module according to an embodiment of the present invention. In this embodiment, the driving module 75 includes four P type transistors D₃, D₄, D₅ and D₆, and a capacitor D_{C}. Shown as in FIG. 7B, a control terminal of the P type transistor D₃ is electrically coupled to the input terminal L to receive the driving signal DRV₁. One source/drain terminal of the P type transistor D₃ is electrically coupled to the driving-signal output terminal O_{d}, and the other source/drain terminal of the P type transistor D₃ is electrically coupled to the preset voltage source VGH. A control terminal of the P type transistor D₄ is also electrically coupled to the input terminal I_{d1} to receive the driving signal DRV₁. One source/drain terminal of the P type transistor D₄ is electrically coupled to the preset voltage source VGH, and the other source/drain terminal of the P type transistor D₄ and one terminal of the capacitor P_{C} are electrically coupled to a node S. The other terminal of the capacitor D_{C} is electrically coupled to the driving-signal output terminal O_{d}. A control terminal of the P type transistor D₅ is also electrically coupled to the input terminal I_{d2} to receive the driving signal DRV₂. One source/drain terminal of the P type transistor D₅ is electrically coupled to the preset voltage source VGL, and the other source/drain terminal of the P type transistor D₅, the other source/drain terminal of the P type transistor D₄ and the terminal of the capacitor D_{C} are electrically coupled to the node S. A control terminal of the P type transistor D₆ is also electrically coupled to the node S, one source/drain terminal of the P type transistor D₆ is electrically coupled to the enable-signal input terminal I_{EN}, and the other source/drain terminal of the P type transistor D₆ is electrically coupled to the driving-signal output terminal O_{d}.

Referring to FIGS. 7B and 7C, FIG. 7C is a waveform diagram of signals respectively corresponding to each node when the circuit in FIG. 7B operates. Shown as in FIG. 7C, during the time points T_{G} and T_{H}, the driving signal DRV₁ is at logic high level, and the driving signal DRV₁ is reversely at logic low level. Therefore, the P type transistors D₃ and D₄ are accordingly turned off, and the P type transistor D₅ is accordingly turned on. Thus, the voltage of the node S is firstly influenced by the P type transistor D₅ and is pulled down to be about equal to the logic low level provided by the preset voltage source VGL, and is then enabled to be equal to the logic low level according to an enabling signal EN on the enable-signal input terminal I_{EN} being enabled. The voltage of the node S is further pulled down to ensure that the voltage of the enabling signal EN can be properly transmitted to the driving-signal output terminal O_{d}.

Outside the interval from time point T_{G} to the time point T_{H}, due to the driving signal DRV₁ at logic low level, and the driving signal DRV₁ at logic high level, the P type transistors D₃ and D₄ are accordingly turned on, and the P type transistor D₅ is accordingly turned off. Therefore, the voltage of the node S is pulled up to be about equal to the logic high level provided by the preset voltage source VGH, and further makes the driving-signal output terminal O_{d} keeping at a level about equal to the logic high level provided by the preset voltage source VGH.

In summary, only during the time points T_{G} and T_{H}, the voltage at the driving-signal output terminal O_{d} (or driver signal SCAN) can be enabled (in this embodiment, being enabled means being at about logic low level). A duration of the enabling signal EN on the enable-signal input terminal I_{EN} determines a duration t₂ when the driver signal SCAN is enabled. That is, the enabled duration of the output signal of the shift register can be properly and dynamically adjusted via the circuit design shown in FIG. 6 or FIGS. 7A and 7B.

In addition, it should be noted that, shown as in FIG. 7C, just the phases of the driving signals DRV₁ and DRV₁ are reverse to each other, it does not need to construct a corresponding circuit restrictively according to FIG. 2 or FIG. 6. In other word, it just needs two signals having phases reverse to each other respectively provided to the input terminals L and I_{d2} as the driving signals DRV₁ and DRV₁, the target of adjusting the enabled duration of the driver signal SCAN can be achieved via the circuit shown in FIG. 7B utilizing the enabling signal EN in different enabling period. Further, although the circuits shown in FIGS. 7A and 7B is designed mainly with P type transistors, the person having ordinary skill in the art can easily change the design to a circuit mainly composed by N type transistors. Due to such change capable of being achieved under a limited modulation, it is not excessively described here.

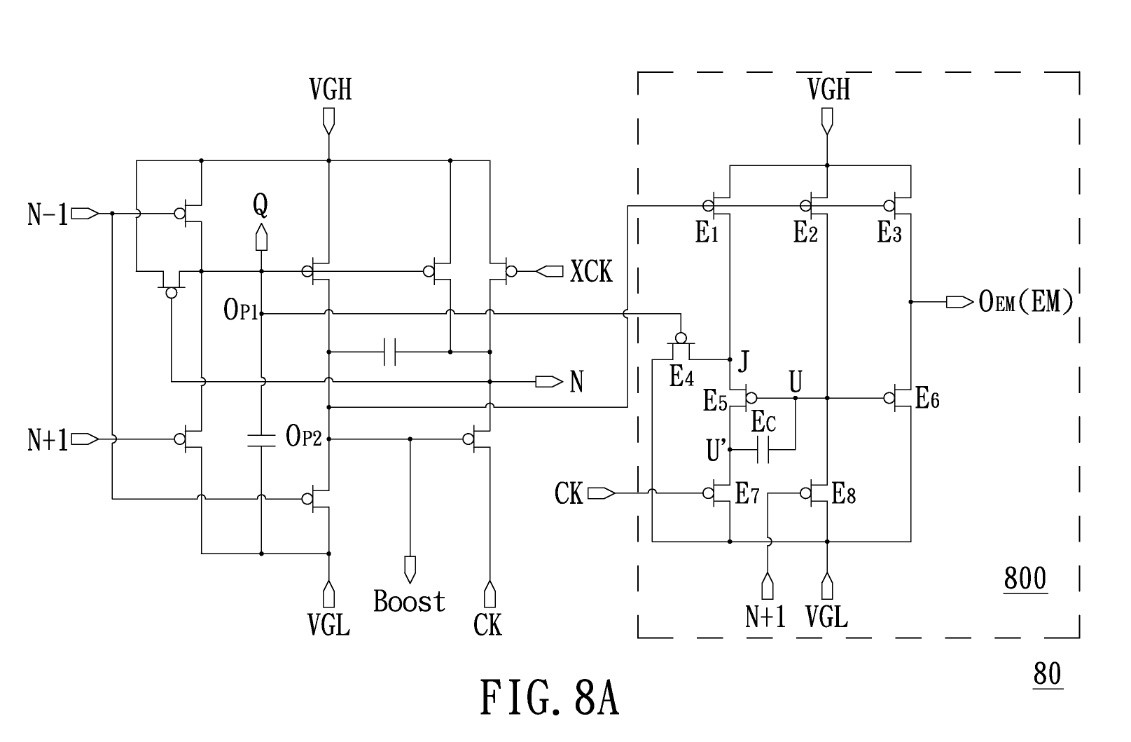

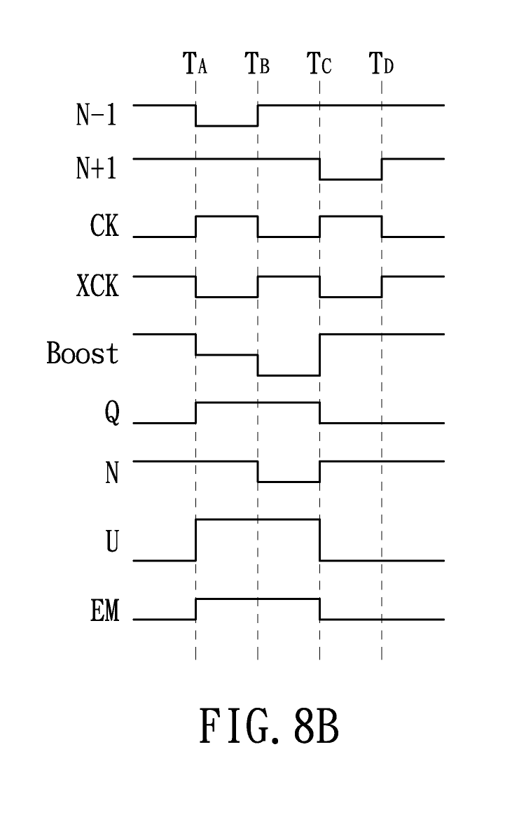

Referring to FIG. 8A, FIG. 8A is a circuit diagram of a shift register according to another more again embodiment of the present invention. In this embodiment, the shift register 80 not only includes all the circuits of the shift register 20, but also further includes an illuminating signal generating unit 800. The illuminating signal generating unit 800 has an illuminating control-signal output terminal O_{EM} to output an illuminating control signal EM. In this embodiment, the illuminating signal generating unit 800 includes eight P type transistors E₁˜E₈ and a capacitor E_{C}, and each P type transistor includes a control terminal and two source/drain terminals.

Shown as in FIG. 8A, the control terminals of the P type transistors E₁, E₂ and E₃ are electrically coupled to the (N−1)th second control-signal output terminal O_{P2} (corresponding to the node Boost), and one source/drain terminal of each of the P type transistors E₁, E₂ and E₃ is electrically coupled to the preset voltage source VGH. The other source/drain terminal of the P type transistor E₁ and one source/drain terminal of the P type transistor E₄ are electrically coupled to a node J, and the other source/drain terminal of the P type transistor E₄ is electrically coupled to the preset voltage source VGL. The control terminal of the P type transistor E₄ is electrically coupled to the (N−1)th first control-signal output terminal O_{P1} (corresponding to the node Q). The other source/drain terminal of the P type transistor E₂ and the control terminals of the P type transistors E₅ and E₆ are electrically coupled to a node U, and the other source/drain terminal of the P type transistor E₃ is electrically coupled to the illuminating control-signal output terminal O_{EM}. Further, one source/drain terminal of the P type transistor E₅ is electrically coupled to the node J, one source/drain terminal of the P type transistor E₆ is electrically coupled to the preset voltage source VGL, and the other source/drain terminal of the P type transistor E₆ is electrically coupled to the illuminating control-signal output terminal O_{EM}. The control terminal of the P type transistor E₇ receives the clock signal CK, one source/drain terminal of the P type transistor E₇ is electrically coupled to the preset voltage source VGL, and the other source/drain terminal of the P type transistor E₇, one terminal of the capacitor E_{C} and the other source/drain terminal of the P type transistor E₅ are electrically coupled to a node U′. The control terminal of the P type transistor E₈ receives the (N+1)th signal N+1, one source/drain terminal of the P type transistor E₈ is electrically coupled to the preset voltage source VGL, and the other source/drain terminal of the P type transistor E₈ and one source/drain terminal of the P type transistor E₂ are electrically coupled to the node U. Two terminals of the capacitor E_{C} are respectively electrically coupled to the node U and the node U′.

Referring to FIGS. 8A and 8B, FIG. 8B is a waveform diagram of signals respectively corresponding to each node when the shift register in FIG. 8A operates. The waveforms of the (N−1)th signal N−1, the (N+1)th signal N+1, the clock signal CK, the reversed clock signal XCK, the voltage of the node Boost, the voltage of the node Q and the output signal N have been illustrated in the above embodiments, and it is not excessively described here. The operation principle of the illuminating signal generating unit 800 will be focused on as follows.

Shown as in FIG. 8, at the time point T_{A}, the voltages of the node Q and the clock signal CK are turned from the logic low level to the logic high level, the voltage of the (N+1)th signal N+1 keeps at the logic high level, and the voltage of the node Boost is turned from the logic high level to the logic low level. Correspondingly, the P type transistors E₁, E₂ and E₃ are turned from the turned-off state to the turned-on state, the P type transistors E₄ and E₇ are turned from the turned-on state to the turned-off state, and the P type transistor E₈ keeps at the turned-off state. Therefore, between the time point T_{A} and the time point T_{B}, the voltages of the node J, the node U and the illuminating control-signal output terminal O_{EM} are pulled up to be equal or close to the logic high level of the preset voltage source VGH respectively via the P type transistors E₁, E₂ and E₃, and thereby the P type transistors E₅ and E₆ are turned off.

At the time point T_{B}, the voltage of the node Q keeps at the logic high level, the voltage of the clock signal CK is turned from the logic high level to the logic low level, the voltage of the (N+1)th signal N+1 keeps at the logic high level, and the voltage of the node Boost is turned from the logic low level to a lower level. Correspondingly, the P type transistors E₁, E₂ and E₃ keep the turned-on state, the P type transistors E₄ and E₈ keep the turned-off state, and the P type transistor E₇ is turned from the turned-off state to the turned-on state. Therefore, between the time point T_{B} and the time point T_{C}, the voltages of the node J, the node U and the illuminating control-signal output terminal O_{EM} are pulled up to be equal or close to the logic high level of the preset voltage source VGH respectively via the P type transistors E₁, E₂ and E₃, and thereby the voltage of the node U′ is pulled down to be equal or close to the logic low level of the preset voltage source VGL via the P type transistor E₇.

At the time point T_{C}, the voltages of the node Q and the (N+1)th signal N+1 are turned from the logic high level to logic low level, the voltage of the clock signal CK is turned from the logic low level to the logic high level, and the voltage of the node Boost is pulled up to the logic high level. Correspondingly, the P type transistors E₁, E₂, E₃ and E₇ are turned from the turned-on state to the turned-off state, and the P type transistors E₄ and E₈ are turned from the turned-off state to the turned-on state. Therefore, between the time point T_{C} and the time point T_{D}, the voltage of the node U is pulled down to be equal or close to the logic low level of the preset voltage source VGL via the P type transistor E₈, and further makes the P type transistors E₅ and E₆ being turned on. Due to the P type transistor E₆ being turned on, the voltage of the illuminating control-signal output terminal O_{EM} is pulled down to be equal or close to the logic low level of the preset voltage source VGL via the P type transistor E₆.

By the above circuit design, the illuminating control signal EM with an enabled duration double than that of the clock signal CK can be obtained (in this embodiment, the illuminating control signal EM is enabled within the logic high level). By adjusting or adding or subtracting some electronic components, the enabled duration of the illuminating control signal EM can be designed to be integral multiple of the enabled duration of the clock signal CK. Such alternative design can be obtained by the person having ordinary skill in the art according to the above embodiment, and it is not excessively described here.

The design according to FIGS. 8A and 8B can provides an accurate multiple relationship between the clock signal CK and the illuminating control signal EM, Therefore, it is particularly suitable for all the displays driven and controlled via analog circuits (e.g., a compensation circuit in AMOLED) to operate.

In summary, the present invention makes a conducting path of providing voltage to the output terminal being sequentially turned on based on stable means. In comparison with the conventional means of proving the voltage to the output terminal via continuously turning on/off the transistors, the means provided by the present invention doubtlessly makes the output voltage more stable. In addition, the design of freely adjusting the enabling duration of the output terminal can make the application of the shift register of the present invention more flexible.

While the present invention has been described in terms of what is presently considered to be the most practical and preferred embodiments, it is to be understood that the present invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A shift register, comprising:
a previous signal receiving unit, comprising a previous signal input terminal, a previous first preset-voltage input terminal, a previous second preset-voltage input terminal, a previous first control-signal output terminal, and a previous second control-signal output terminal, wherein the previous signal input terminal receives a previous signal, the previous first preset-voltage input terminal is electrically coupled to a first preset-voltage source, the previous second preset-voltage input terminal is electrically coupled to a second preset-voltage source, and the previous signal receiving unit controls degrees of an electrical conduction between the previous first preset-voltage input terminal and the previous first control-signal output terminal according to a voltage of the previous signal, and controls degrees of an electrical conduction between the previous second preset-voltage input terminal and the previous second control-signal output terminal according to the voltage of the previous signal;
a next signal receiving unit, comprising a next signal input terminal, a next second preset-voltage input terminal, and a next control-signal output terminal, wherein the next signal input terminal receives a next signal, the next second preset-voltage input terminal is electrically coupled to the second preset-voltage source, the next control-signal output terminal is electrically coupled to the previous first control-signal output terminal, and the next signal receiving unit controls degrees of an electrical conduction between the next second preset-voltage input terminal and the next control-signal output terminal according to a voltage of the next signal;
a control unit, comprising a first preset-voltage input terminal, a clock-signal input terminal, a reversed clock-signal input terminal, a first control-signal input terminal, a second control-signal input terminal, and an output terminal, wherein the first preset-voltage input terminal is electrically coupled to the first preset voltage source, the clock-signal input terminal receives a clock signal, the reversed clock-signal input terminal receives a reversed clock signal having a phase reversed to that of the clock signal, the first control-signal input terminal is electrically coupled to the previous first control-signal output terminal, the second control-signal input terminal is electrically coupled to the previous second control-signal output terminal, and the control unit controls degrees of an electrical conduction between the clock-signal input terminal and the output terminal according to voltages of the reversed clock-signal input terminal, the first control-signal input terminal and the second control-signal input terminal; and
a voltage stabilizing switch, comprising a control terminal, a first source/drain terminal and a second source/drain terminal, wherein the control terminal is electrically coupled to the output terminal of the control unit, the first source/drain terminal is electrically coupled to the previous first control-signal output terminal, and the second source/drain terminal is electrically coupled to the previous first preset-voltage input terminal of the previous signal receiving unit.

2. The shift register as claimed in claim 1, wherein the previous signal receiving unit comprising:
a first transistor, comprising a control terminal, a first source/drain terminal and a second source/drain terminal, wherein the control terminal thereof is electrically coupled to the previous signal input terminal, the first source/drain terminal thereof is electrically coupled to the previous first control-signal output terminal, and the second source/drain terminal thereof is electrically coupled to the previous first preset-voltage input terminal; and
a second transistor, comprising a control terminal, a first source/drain terminal and a second source/drain terminal, wherein the control terminal thereof is electrically coupled to the previous signal input terminal, the first source/drain terminal thereof is electrically coupled to the previous second preset-voltage input terminal, and the second source/drain terminal thereof is electrically coupled to the previous second control-signal output terminal.

3. The shift register as claimed in claim 1, wherein the next signal receiving unit comprising:
a transistor, comprising a control terminal, a first source/drain terminal and a second source/drain terminal, wherein the control terminal thereof is electrically coupled to the next signal input terminal, the first source/drain terminal thereof is electrically coupled to the next second preset-voltage input terminal, and the second source/drain terminal thereof is electrically coupled to the next control-signal output terminal; and
a capacitor, one terminal thereof is electrically coupled to the next second preset-voltage input terminal, and the other terminal thereof is electrically coupled to the next control-signal output terminal.

4. The shift register as claimed in claim 1, wherein the control unit comprising:
a first transistor, comprising a control terminal, a first source/drain terminal and a second source/drain terminal, wherein the control terminal thereof is electrically coupled to the second control-signal input terminal, the first source/drain terminal thereof is electrically coupled to the timing-signal input terminal, and the second source/drain terminal thereof is electrically coupled to the output terminal;
a second transistor, comprising a control terminal, a first source/drain terminal and a second source/drain terminal, wherein the control terminal thereof is electrically coupled to the first control-signal input terminal, the first source/drain terminal thereof is electrically coupled to the second control-signal input terminal, and the second source/drain terminal thereof is electrically coupled to the first preset-voltage input terminal;
a third transistor, comprising a control terminal, a first source/drain terminal and a second source/drain terminal, wherein the control terminal thereof is electrically coupled to the first control-signal input terminal, the first source/drain terminal thereof is electrically coupled to the output terminal, and the second source/drain terminal thereof is electrically coupled to the first preset-voltage input terminal;
a fourth transistor, comprising a control terminal, a first source/drain terminal and a second source/drain terminal, wherein the control terminal thereof is electrically coupled to the reversed timing-signal input terminal, the first source/drain terminal thereof is electrically coupled to the output terminal, and the second source/drain terminal thereof is electrically coupled to the first preset-voltage input terminal; and
a capacitor, one terminal thereof is electrically coupled to the output terminal, and the other terminal thereof is electrically coupled to the second control-signal input terminal.

5. The shift register as claimed in claim 1, further comprising:
a first transistor, comprising a control terminal, a first source/drain terminal and a second source/drain terminal, wherein the control terminal thereof receives the previous signal, the first source/drain terminal thereof is electrically coupled to the previous first preset-voltage input terminal of the previous signal receiving unit, and the second source/drain terminal thereof is electrically coupled to the first preset-voltage source;
a second transistor, comprising a control terminal, a first source/drain terminal and a second source/drain terminal, wherein the control terminal thereof is electrically coupled to the output terminal of the control unit, the first source/drain terminal thereof is electrically coupled to the previous first preset-voltage input terminal of the previous signal receiving unit, and the second source/drain terminal thereof is electrically coupled to the first preset-voltage source; and
a third transistor, comprising a control terminal, a first source/drain terminal and a second source/drain terminal, wherein the control terminal thereof is electrically coupled to the previous first control-signal output terminal of the previous signal receiving unit, the first source/drain terminal thereof is electrically coupled to the second preset-voltage source, and the second source/drain terminal thereof is electrically coupled to the previous first preset-voltage input terminal of the previous signal receiving unit.

6. The shift register as claimed in claim 1, further comprising:
a driving-signal generating module, providing a first driving signal, wherein a phase of the first driving signal is reverse to a phase of a second driving signal composed by a voltage outputted from the output terminal of the control unit; and
a driving module, comprising a first input terminal, a second input terminal, a driving module first preset-voltage input terminal, a driving module second preset-voltage input terminal, an enable-signal input terminal, and a driving-signal output terminal, wherein the first input terminal is electrically coupled to the driving-signal generating module to receive the first driving signal, the second input terminal is electrically coupled to the output terminal of the control unit to receive the second driving signal, and the driving module controls degrees of an electrical conduction between the driving module first preset-voltage input terminal and the driving-signal output terminal according to the first driving signal, and controls degrees of an electrical conduction between the enable-signal input terminal and the driving-signal output terminal according to the second driving signal.

7. The shift register as claimed in claim 6, wherein the driving-signal generating module comprising:
a first transistor, comprising a control terminal, a first source/drain terminal and a second source/drain terminal, wherein the control terminal thereof is electrically coupled to the previous first control-signal output terminal of the previous signal receiving unit, the first source/drain terminal thereof is electrically coupled to the first input terminal of the driving module, and the second source/drain terminal thereof is electrically coupled to the second preset-voltage source; and
a second transistor, comprising a control terminal, a first source/drain terminal and a second source/drain terminal, wherein the control terminal thereof is electrically coupled to the previous second control-signal output terminal of the previous signal receiving unit, the first source/drain terminal thereof receives the reversed clock signal, and the second source/drain terminal thereof is electrically coupled to the first input terminal of the driving module.

8. The shift register as claimed in claim 6, wherein the driving module comprising:
a first transistor, comprising a control terminal, a first source/drain terminal and a second source/drain terminal, wherein the control terminal thereof is electrically coupled to the first input terminal, the first source/drain terminal thereof is electrically coupled to the driving-signal output terminal, and the second source/drain terminal thereof is electrically coupled to the first preset-voltage source;
a second transistor, comprising a control terminal, a first source/drain terminal and a second source/drain terminal, wherein the control terminal thereof is electrically coupled to the first input terminal, and the first source/drain terminal thereof is electrically coupled to the first preset-voltage source;
a third transistor, comprising a control terminal, a first source/drain terminal and a second source/drain terminal, wherein the control terminal thereof is electrically coupled to the second input terminal, the first source/drain terminal thereof is electrically coupled to the second preset-voltage source, and the second source/drain terminal thereof is electrically coupled to the second source/drain terminal of the second transistor;
a fourth transistor, comprising a control terminal, a first source/drain terminal and a second source/drain terminal, wherein the control terminal thereof is electrically coupled to the second source/drain terminal of the third transistor, the first source/drain terminal thereof is electrically coupled to the enable-signal input terminal, and the second source/drain terminal thereof is electrically coupled to the driving-signal output terminal; and
a capacitor, one terminal thereof is electrically coupled to the driving-signal output terminal, and the other terminal thereof is electrically coupled to the second source/drain terminal of the second transistor.

9. The shift register of claim 1, further comprising:
an illuminating signal generating unit with an illuminating control-signal output terminal to output an illuminating control signal, comprising:
a first transistor, comprising a control terminal, a first source/drain terminal and a second source/drain terminal, wherein the control terminal thereof is electrically coupled to the previous second control-signal output terminal of the previous signal receiving unit, and the first source/drain terminal thereof is electrically coupled to the first preset-voltage source;
a second transistor, comprising a control terminal, a first source/drain terminal and a second source/drain terminal, wherein the control terminal thereof is electrically coupled to the previous second control-signal output terminal of the previous signal receiving unit, and the first source/drain terminal thereof is electrically coupled to the first preset-voltage source;
a third transistor, comprising a control terminal, a first source/drain terminal and a second source/drain terminal, wherein the control terminal thereof is electrically coupled to the previous second control-signal output terminal of the previous signal receiving unit, the first source/drain terminal thereof is electrically coupled to the first preset-voltage source, and the second source/drain terminal thereof is electrically coupled to the illuminating control-signal output terminal;
a fourth transistor, comprising a control terminal, a first source/drain terminal and a second source/drain terminal, wherein the control terminal thereof is electrically coupled to the previous first control-signal output terminal of the previous signal receiving unit, the first source/drain terminal thereof is electrically coupled to the second preset-voltage source, and the second source/drain terminal thereof is electrically coupled to the second source/drain terminal of the first transistor;
a fifth transistor, comprising a control terminal, a first source/drain terminal and a second source/drain terminal, wherein the control terminal thereof is electrically coupled to the second source/drain terminal of the second transistor, and the first source/drain terminal thereof is electrically coupled to the second source/drain terminal of the first transistor;
a sixth transistor, comprising a control terminal, a first source/drain terminal and a second source/drain terminal, wherein the control terminal thereof is electrically coupled to the second source/drain terminal of the second transistor, the first source/drain terminal thereof is electrically coupled to the illuminating control-signal output terminal, and the second source/drain terminal thereof is electrically coupled to the second preset-voltage source;
a seventh transistor, comprising a control terminal, a first source/drain terminal and a second source/drain terminal, wherein the control terminal thereof receives the clock signal, the first source/drain terminal thereof is electrically coupled to the second source/drain terminal of the fifth transistor, and the second source/drain terminal thereof is electrically coupled to the second preset-voltage source;
an eighth transistor, comprising a control terminal, a first source/drain terminal and a second source/drain terminal, wherein the control terminal thereof receives the next signal receiving, the first source/drain terminal thereof is electrically coupled to the second source/drain terminal of the second transistor, and the second source/drain terminal thereof is electrically coupled to the second preset-voltage source;
a capacitor, one terminal thereof is electrically coupled to the second source/drain terminal of the second transistor, and the other terminal thereof is electrically coupled to the second source/drain terminal of the fifth transistor.

10. A shift register, comprising:
a driving-signal generating module, providing a first driving signal and a second driving signal, wherein a phase of the first driving signal is reverse to a phase of the second driving signal; and
a driving module, comprising a first input terminal, a second input terminal, a driving module first preset-voltage input terminal, a driving module second preset-voltage input terminal, an enable-signal input terminal, and a driving-signal output terminal, wherein the driving module is electrically coupled to the driving-signal generating module to receive the first driving signal via the first input terminal and receive the second driving signal via the second input terminal, and the driving module controls degrees of an electrical conduction between the driving module first preset-voltage input terminal and the driving-signal output terminal according to the first driving signal, and controls degrees of an electrical conduction between the enable-signal input terminal and the driving-signal output terminal according to the second driving signal;
wherein an enabled duration of the enable-signal input terminal determines an enabled duration of the driving-signal output terminal.

11. The shift register as claimed in claim 10, wherein the driving module comprising:
a first transistor, comprising a control terminal, a first source/drain terminal and a second source/drain terminal, wherein the control terminal thereof is electrically coupled to the first input terminal, the first source/drain terminal thereof is electrically coupled to the driving-signal output terminal, and the second source/drain terminal thereof is electrically coupled to the first preset-voltage source;
a second transistor, comprising a control terminal, a first source/drain terminal and a second source/drain terminal, wherein the control terminal thereof is electrically coupled to the first input terminal, and the first source/drain terminal thereof is electrically coupled to the first preset-voltage source;
a third transistor, comprising a control terminal, a first source/drain terminal and a second source/drain terminal, wherein the control terminal thereof is electrically coupled to the second input terminal, the first source/drain terminal thereof is electrically coupled to the second preset-voltage source, and the second source/drain terminal thereof is electrically coupled to the second source/drain terminal of the second transistor;
a fourth transistor, comprising a control terminal, a first source/drain terminal and a second source/drain terminal, wherein the control terminal thereof is electrically coupled to the second source/drain terminal of the third transistor, the first source/drain terminal thereof is electrically coupled to the enable-signal input terminal, and the second source/drain terminal thereof is electrically coupled to the driving-signal output terminal; and
a capacitor, one terminal thereof is electrically coupled to the driving-signal output terminal, and the other terminal thereof is electrically coupled to the second source/drain terminal of the second transistor.
